(19) United States
(12) Patent Application Publication
(10) Pub. No.: US 2022/0254626 A1
(43) Pub. Date: Aug. 11, 2022

(54) SEMICONDUCTOR STRUCTURE AND MANUFACTURING METHOD THEREOF

(71) Applicant: CHANGXIN MEMORY TECHNOLOGIES, INC., Hefei City, Anhui (CN)

(72) Inventor: Shuai HUANG, Hefei City, Anhui (CN)

(21) Appl. No.: 17/595,656

(22) PCT Filed: Feb. 20, 2021
(86) PCT No.: PCT/CN2021/077012

§ 371 Date: Nov. 22, 2021

(30) Foreign Application Priority Data
Feb. 28, 2020 (CN) 202010129156.5

(51) Int. Cl. H01L 21/027; H01L 21/311; H01L 21/3213

(52) U.S. Cl. CPC H01L 21/0274; H01L 21/31116; H01L 21/32139; H01L 21/32135; H01L 21/31144

(57) ABSTRACT

Disclosed are a semiconductor structure and a manufacturing method thereof. The manufacturing method of a semiconductor structure includes: providing a to-be-etched layer; forming a photoresist layer on a surface of the to-be-etched layer; exposing the photoresist layer, the exposed photoresist layer including a mask portion and a to-be-removed portion; forming an acting material layer on a surface of the photoresist layer; the acting material layer interacting with the mask portion to form a mask layer on the top of the mask portion; removing the residual acting material layer; and etching and removing the to-be-removed portion based on the mask layer, to form a mask pattern.

### CROSS-REFERENCE TO RELATED APPLICATION

This application claims priority to Chinese Patent Application No. 202010129156.5, titled “SEMICONDUCTOR STRUCTURE AND MANUFACTURING METHOD THEREOF” and filed on Feb. 28, 2020, the entire contents of which are incorporated herein by reference.

### TECHNICAL FIELD

The present invention relates to a semiconductor structure and a manufacturing method thereof.

### BACKGROUND

Photoetching is a process in which a particular part of a film on a surface of a wafer is removed through a series of manufacturing steps. After that, a film with a micrographic structure may be left on the surface of the wafer. Through the photoetching process, the final part left on the wafer is a characteristic pattern. A general photoetching process includes working procedures such as silicon wafer surface cleaning and drying, precoating, spin-coating photoresist, soft baking, alignment exposure, post-baking, development, hard baking, etching, and detection.

### SUMMARY

According to various embodiments, the present invention provides a manufacturing method of a semiconductor structure, including: providing a to-be-etched layer; forming a photoresist layer on a surface of the to-be-etched layer; exposing the photoresist layer, the exposed photoresist layer including a mask portion and a to-be-removed portion; forming an acting material layer on a surface of the photoresist layer; the acting material layer interacting with the mask portion to form a mask layer on the top of the mask portion; removing the residual acting material layer; and etching and removing the to-be-removed portion based on the mask layer, to form a mask pattern.

According to various embodiments, the present invention further provides a semiconductor structure, including: a to-be-etched layer; an exposed photoresist layer located on a surface of the to-be-etched layer, the photoresist layer including a mask portion and a to-be-removed portion; an acting material layer located on a surface of the photoresist layer; and a mask layer located at the top of the mask portion; the mask layer being formed by interaction between the acting material layer and the mask portion.

Details of one or more embodiments of the present application are set forth in the following accompanying drawings and descriptions. Other features and advantages of the present application become obvious with reference to the specification, the accompanying drawings, and the claims.

### BRIEF DESCRIPTION OF DRAWINGS

In order to more clearly illustrate the technical solutions in embodiments of the present application or the conventional technology, the accompanying drawings used in the description of the embodiments or the conventional technology will be briefly introduced below. It is apparent that, the accompanying drawings in the following description are only some embodiments of the present application, and other drawings can be obtained by those of ordinary skill in the art from the provided drawings without creative efforts.

FIG. 1 is a flowchart of a manufacturing method of a semiconductor structure according to the present invention; and

FIG. 2 to FIG. 10 are schematic diagrams of structures presented by steps in the manufacturing method of the semiconductor structure according to the present invention, in which FIG. 6 is a schematic diagram of a structure presented by the semiconductor structure according to the present invention.

In the drawings, 10: to-be-etched layer; 20: photoresist layer; 201: mask portion; 202: to-be-removed portion; 30: acting material layer; 301: acting material layer; 40: mask layer; 50: mask pattern; 60: etching pattern.

### DESCRIPTION OF EMBODIMENTS

A patterned photoresist layer formed after an exposed photoresist layer is developed is often inclined, which leads to an inaccurate micrographic structure formed later.

To facilitate understanding of the present invention, a more comprehensive description of the present invention will be given below with reference to the relevant accompanying drawings. Preferred embodiments of the present invention are given in the drawings. However, the present invention may be implemented in many different forms and is not limited to the embodiments described herein. Rather, these embodiments are provided to make the contents disclosed in the present invention more fully understood.

Unless defined otherwise, all technical and scientific terms used herein have the same meanings as are commonly understood by those skilled in the art. The terms used herein in the specification of the present invention are for the purpose of describing specific embodiments only but not intended to limit the present invention. The term “and/or” used herein includes any and all combinations of one or more related listed items.

In the description of the present invention, it should be understood that, the orientation or position relationship indicated by the terms “upper”, “lower”, “vertical”, “horizontal”, “inner”, “outer”, and the like, are the orientation or position relationship illustrated in the drawings, which is only used to facilitate the description of the present invention and simplify the description, rather than indicate or imply that an apparatus or element must have a specific orientation, be configured or operate in the specific orientation, and thus cannot be constructed as any limitation on the present invention.

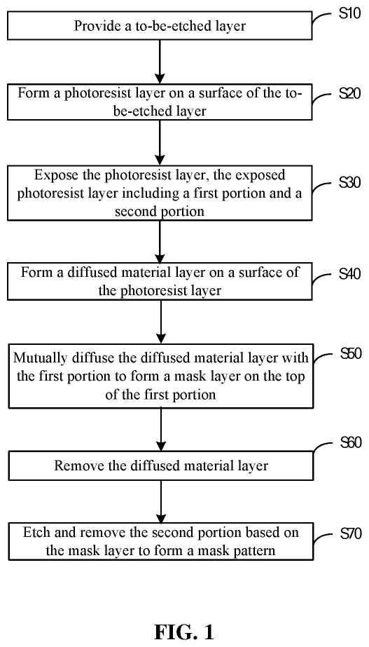

In one embodiment, as shown in FIG. 1, a manufacturing method of a semiconductor structure is provided, including: providing a to-be-etched layer 10; forming a photoresist layer 20 on a surface of the to-be-etched layer 10; exposing the photoresist layer 20, the exposed photoresist layer 20 including a mask portion 201 and a to-be-removed portion 202; forming an acting material layer 30 on a surface of the photoresist layer 20; the acting material layer 30 interacting with the mask portion 201 to form a mask layer 40 on the top of the mask portion 201; removing the residual acting material layer 301; and etching and removing the to-be-removed portion 202 based on the mask layer 40, to form a mask pattern 50.

In the present embodiment, the manufacturing method of the semiconductor structure can avoid tilt of the mask pattern 50, so that an etching pattern 60 formed later is more accurate, thereby improving the quality of the device and the yield of the product.

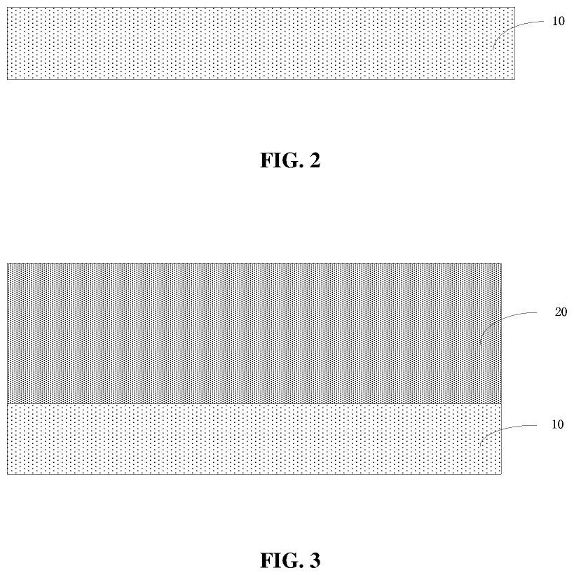

In S10, as shown in FIG. 2, the to-be-etched layer 10 is provided.

In one embodiment, a material of the to-be-etched layer 10 includes, but not limited to, a silicon oxide layer, a silicon nitride layer, a polycrystalline silicon layer, a low-K dielectric material, amorphous carbon, or a metal layer or any combination thereof.

In S20, as shown in FIG. 3, the photoresist layer 20 is formed on the surface of the to-be-etched layer 10.

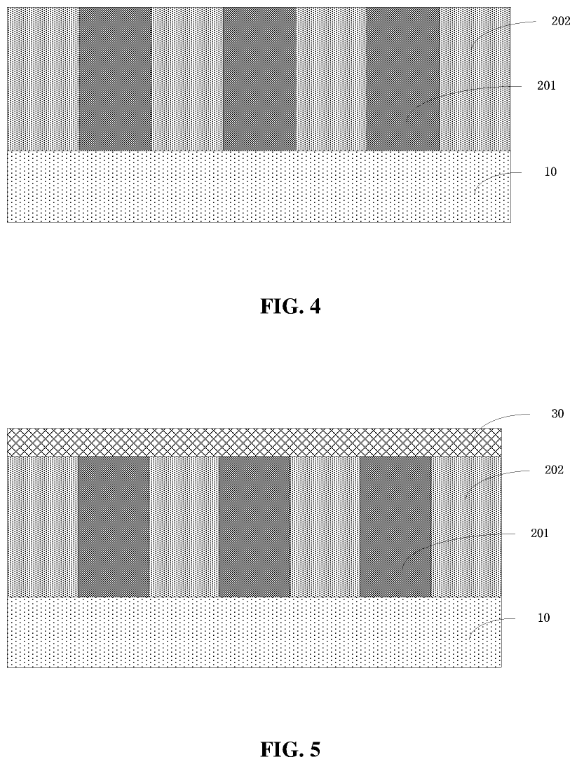

The photoresist layer 20 includes a photosensitive resin, a sensitizer and a solvent. In S30, as shown in FIG. 4, the photoresist layer 20 is exposed, the exposed photoresist layer 20 including the mask portion 201 and the to-be-removed portion 202.

The photoresist layer 20 is exposed by selective irradiation.

In one embodiment, the mask portion 201 includes an exposed region, and the to-be-removed portion 202 includes a non-exposed region. In this case, the photoresist layer 20 is a negative photoresist layer 20.

In another embodiment, the mask portion 201 includes a non-exposed region, and the to-be-removed portion 202 includes an exposed region. In this case, the photoresist layer 20 is a positive photoresist layer 20.

In one embodiment, the mask portion 201 includes an acidic polymer.

In S40, as shown in FIG. 5, the acting material layer 30 is formed on the surface of the photoresist layer 20.

In one embodiment, the acting material layer 30 includes a metal-containing alkaline material layer or an organic metal polymer material layer.

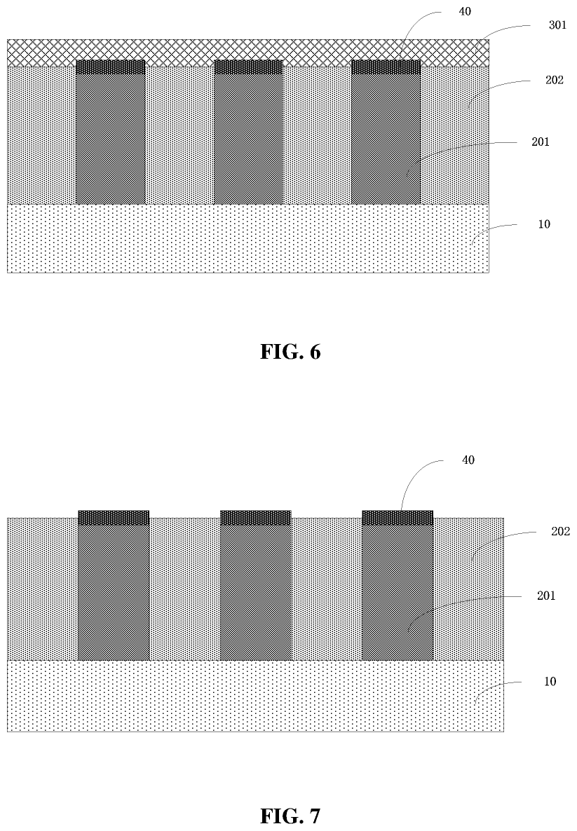

In S50, as shown in FIG. 6, the acting material layer 30 interacts with the mask portion 201 to form the mask layer 40 on the top of the mask portion 201.

The mask layer 40 has a higher etching selectivity than the to-be-removed portion 202 and the acting material layer 30, so as to ensure that the mask layer 40 can be retained completely when the to-be-removed portion 202 and the acting material layer 30 are etched and removed, and the mask layer 40 has a smaller thickness.

In one embodiment, the interaction between the acting material layer 30 and the mask portion 201 includes a mutual chemical reaction, mutual physical absorption or one-way adsorption.

In one embodiment, step S50 includes: mutually diffusing the acting material layer 30 with the mask portion 201 to form the mask layer 40 on the top of the mask portion 201.

In one embodiment, step S50 includes: carrying out heat treatment on the acting material layer 30 and the mask portion 201 to make the acting material layer 30 mutually diffused with the mask portion 201.

The heat treatment may be performed by a hot plate.

In one embodiment, a time of the heat treatment is between 0.5 minutes and 12 minutes. For example, the time of the heat treatment may be 4 minutes, 7 minutes, 9 minutes or 12 minutes. A temperature of the heat treatment is between 50° C. and 160° C. For example, the temperature of the heat treatment may be 50° C., 80° C., 120° C. or 160° C.

The diffusion is affected by the temperature of the heat treatment. The higher the temperature, the greater the degree of diffusion.

In S60, as shown in FIG. 7, the residual acting material layer 301 is removed.

In one embodiment, the residual acting material layer 301 is removed by wet etching or dry etching.

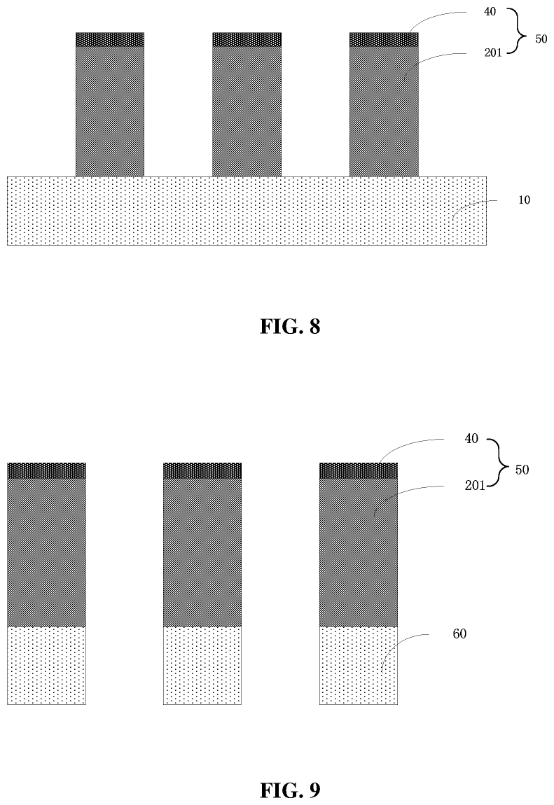

In S70, as shown in FIG. 8, the to-be-removed portion 202 is etched and removed based on the mask layer 40, to form the mask pattern 50.

In one embodiment, the o-be-removed portion 202 is etched and removed by dry etching.

In one embodiment, after step S70, the method further includes the following step.

In S80, as shown in FIG. 9, the to-be-etched layer 10 is etched based on the mask pattern 50, to form the etching pattern 60.

In one embodiment, after step S80, the method further includes the following step.

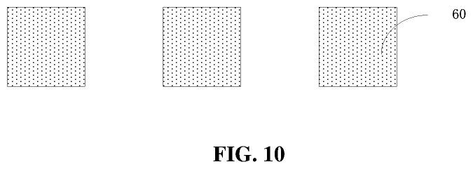

In S90, as shown in FIG. 10, the mask pattern 50 and the mask layer 40 are removed.

A general photoetching process includes working procedures such as silicon wafer surface cleaning and drying, precoating, spin-coating photoresist, soft baking, alignment exposure, post-baking, development, hard baking, etching, and detection. During the development, a photoresist pattern formed by development may be inclined, thus affecting the accuracy of the pattern. In the present invention, the acting material layer 30 is formed on the surface of the photoresist layer 20, the acting material layer 30 intersects with the mask portion 201 to form the mask layer 40 on the top of the mask portion 201, the residual acting material layer 301 is removed, and the to-be-removed portion 202 is etched and removed based on the mask layer 40 to form the mask pattern 50. Since the mask layer 40 is not easy to tilt, the accuracy of the etching pattern 60 can be ensured.

In one embodiment, as shown in FIG. 6, a semiconductor structure is provided, including: a to-be-etched layer 10; an exposed photoresist layer 20 located on a surface of the to-be-etched layer 10, the photoresist layer 20 including a mask portion 201 and a to-be-removed portion 202; an acting material layer 301 located on a surface of the photoresist layer 20; and a mask layer 40 located at the top of the mask portion 201; the mask layer 40 being formed by interaction between the acting material layer 30 and the mask portion 201.

In the present embodiment, the semiconductor structure can avoid tilt of a mask pattern 50 formed later, so that an etching pattern 60 formed later is more accurate, thereby improving the quality of the device and the yield of the product. In one embodiment, the mask portion 201 includes an exposed region.

In one embodiment, a material of the to-be-etched layer 10 includes, but not limited to, a silicon oxide layer, a silicon nitride layer, a polycrystalline silicon layer, a low-K dielectric material, amorphous carbon, or a metal layer or any combination thereof.

In one embodiment, the mask portion 201 includes an exposed region, and the to-be-removed portion 202 includes a non-exposed region.

In one embodiment, the mask portion 201 includes a non-exposed region, and the to-be-removed portion 202 includes an exposed region.

In one embodiment, the acting material layer 30 includes a metal-containing alkaline material layer or an organic metal polymer material layer.

In one embodiment, the mask portion 201 includes an acidic polymer.

Technical features of the above embodiments may be combined randomly. To make descriptions brief, not all possible combinations of the technical features in the embodiments are described. Therefore, as long as there is no contradiction between the combinations of the technical features, they should all be considered as scopes disclosed in the specification.

The above embodiments only describe several implementations of the present invention, which are described specifically and in detail, and therefore cannot be construed as a limitation on the patent scope of the present invention. It should be pointed out that those of ordinary skill in the art may make various changes and improvements without departing from the ideas of the present invention, which shall all fall within the protection scope of the present invention. Therefore, the patent protection scope of the present invention shall be subject to the appended claims.

1. A manufacturing method of a semiconductor structure, comprising:
providing a to-be-etched layer;
forming a photoresist layer on a surface of the to-be-etched layer;
exposing the photoresist layer, the exposed photoresist layer comprising a mask portion and a to-be-removed portion;
forming an acting material layer on a surface of the photoresist layer; the acting material layer interacting with the mask portion to form a mask layer on a top of the mask portion;
removing the residual acting material layer; and
etching and removing the to-be-removed portion based on the mask layer, to form a mask pattern.

2. The manufacturing method of a semiconductor structure according to claim 1, wherein after the mask pattern is formed, the method further comprises: etching the to-be-etched layer based on the mask pattern, to form an etching pattern.

3. The manufacturing method of a semiconductor structure according to claim 1, wherein the acting material layer comprises a metal-containing alkaline material layer or an organic metal polymer material layer.

4. The manufacturing method of a semiconductor structure according to claim 1, wherein the acting material layer is mutually diffused with the mask portion to form the mask layer on the top of the mask portion.

5. The manufacturing method of a semiconductor structure according to claim 4, wherein the acting material layer being mutually diffused with the mask portion comprises: carrying out heat treatment on the acting material layer and the mask portion to make the acting material layer mutually diffused with the mask portion.

6. The manufacturing method of a semiconductor structure according to claim 5, wherein a time of the heat treatment is between 0.5 minutes and 12 minutes, and a temperature of the heat treatment is between 50° C. and 160° C.

7. The manufacturing method of a semiconductor structure according to claim 5, wherein a time of the heat treatment is 4 minutes, 7 minutes, 9 minutes or 12 minutes.

8. The manufacturing method of a semiconductor structure according to claim 5, wherein a material of the to-be-etched layer comprises a silicon oxide layer, a silicon nitride layer, a polycrystalline silicon layer, a low-K dielectric material, amorphous carbon, or a metal layer or any combination thereof.

9. The manufacturing method of a semiconductor structure according to claim 1, wherein the photoresist layer comprises a photosensitive resin, a sensitizer and a solvent.

10. The manufacturing method of a semiconductor structure according to claim 1, wherein the mask portion comprises an exposed region, and the to-be-removed portion comprises a non-exposed region.

11. The manufacturing method of a semiconductor structure according to claim 1, wherein the mask portion comprises a non-exposed region, and the to-be-removed portion comprises an exposed region.

12. The manufacturing method of a semiconductor structure according to claim 1, wherein the acting material layer 30 comprises a metal-containing alkaline material layer or an organic metal polymer material layer.

13. The manufacturing method of a semiconductor structure according to claim 1, wherein the interaction between the acting material layer and the mask portion comprises a mutual chemical reaction, mutual physical absorption or one-way adsorption.

14. The manufacturing method of a semiconductor structure according to claim 1, wherein the residual acting material layer is removed by wet etching or dry etching.

15. A semiconductor structure, comprising:
a to-be-etched layer;
an exposed photoresist layer located on a surface of the to-be-etched layer, the photoresist layer comprising a mask portion and a to-be-removed portion;
an acting material layer located on a surface of the photoresist layer; and
a mask layer located at a top of the mask portion; the mask layer being formed by interaction between the acting material layer and the mask portion.

16. The semiconductor structure according to claim 15, wherein the mask portion comprises an exposed region, and the to-be-removed portion comprises a non-exposed region.

17. The semiconductor structure according to claim 15, wherein the mask portion comprises a non-exposed region, and the to-be-removed portion comprises an exposed region.

18. The semiconductor structure according to claim 15, wherein the acting material layer comprises a metal-containing alkaline material layer or an organic metal polymer material layer.

19. The semiconductor structure according to claim 15, wherein the interaction between the acting material layer and the mask portion comprises a mutual chemical reaction, mutual physical absorption or one-way adsorption.

20. The semiconductor structure according to claim 15, wherein a material of the to-be-etched layer comprises a silicon oxide layer, a silicon nitride layer, a polycrystalline silicon layer, a low-K dielectric material, amorphous carbon, or a metal layer or any combination thereof.
